(19) United States
(12) Patent Application Publication
(10) Pub. No.: US 2006/0145259 A1
(43) Pub. Date: Jul. 6, 2006

(54) Fin field-effect transistor and method for fabricating the same

(76) Inventor: Jeong Ho Park, Icheon-city (KR)

Correspondence Address: Song K. Jung;MCKENNA LONG & ALDRIDGE LLP, 1900 K Street, N.W., Washington, DC, 20006, US

(21) Appl. No.: 11/319,263

(22) Filed: Dec. 29, 2005

(30) Foreign Application Priority Data
Dec. 30, 2004 (KR) 10-2004-0117262

(51) Int. Cl. H01L 27/12; H01L 21/336

(52) U.S. Cl. 257/351; 257/401; 438/284

(57) ABSTRACT

A fin field-effect transistor and a method of fabricating the same provide a fin structure with rounded edges that may prevent a localized thinning of a gate insulating layer formed over the fin structure and to thereby prevent the occurrence of electrical shorts between the fin and a conductive layer formed on the gate insulating layer. The fin field-effect transistor includes an insulating layer formed on an entire surface of a semiconductor substrate where a device isolation layer is formed; a fin formed on the insulating layer, the fin having rounded edges; a gate insulating layer formed on a surface of the fin; and a gate electrode formed on the gate insulating layer to be disposed on three sides of the fin.

### CROSS REFERENCE TO RELATED APPLICATIONS

This application claims the benefit of Korean Patent Application No. 10-2004-0117262, filed on Dec. 30, 2004, which is hereby incorporated by reference as if fully set forth herein.

### BACKGROUND OF THE INVENTION

1. Field of the Invention

The present invention relates to semiconductor devices, and more particularly, to a fin field-effect transistor and a method of fabricating the same, in which a fin structure is provided with rounded edges so that it may prevent a localized thinning of a gate insulating layer formed over the fin structure and thereby prevent the occurrence of electrical shorts between the fin and a conductive layer formed on the gate insulating layer.

2. Discussion of the Related Art

A MOS field-effect transistor that is mainly used for a memory semiconductor device, such as a conventional DRAM device, is a substantially planar transistor where a gate insulating layer covers a surface of a silicon substrate with a conductive layer formed on the gate insulating layer. With increased integration, the line width of a gate pattern and the length and width of a channel are reduced, deteriorating transistor operation by, for example, increasing short-channel and narrow-channel effects. Along with the higher integration, a driving current flowing through a substrate channel, underlying the gate electrode in each cell, may flow through a greatly limited depth and width of the channel adjacent to the gate electrode. Limiting the current levels degrades transistor characteristics.

To overcome short-channel effects and the driving current limitation, the MOS field-effect transistor may be provided with a fin structure to enlarge a contact surface area, existing between the substrate and the gate electrode in a shallow junction structure, and thus enable increased levels in the driving current. A typical fin field-effect transistor, known as a “finFET,” is shown in FIGS. 1 and 2.

Referring to FIGS. 1 and 2, the typical fin field-effect transistor includes a semiconductor substrate 100 where a device isolation layer (not shown) is formed, an insulating layer 101 formed on the entire surface of the semiconductor substrate, a fin 105 formed on the insulating layer, a gate insulating layer 130 formed on a surface of the fin 105, and a gate electrode 106 formed on the gate insulating layer to be disposed on three sides (top side and two lateral sides) of the lengthwise structure of the fin by crossing the fin structure at substantially right angles. Source/drain regions (not shown) are formed, proximate to each other, in a surface region of the fin 105 on either side of the gate electrode 106 that crosses over the fin and connects the source and drain regions.

The upper surfaces of the fin 105 include sharply angled edges A. When the gate insulating layer 130 is formed on the surface of the fin 105, there is, therefore, an inherent thinning of the gate insulating layer at the edges A which deteriorates characteristics of the gate insulating layer. For instance, the thinning phenomenon may generate localized fissuring or lead to the occurrence of minute gaps, so that, when the gate electrode 106 is subsequently formed on the fin 105, an undesirable electrical connection (short) is made between the gate electrode and the fin. This lowers product yield.

### SUMMARY OF THE INVENTION

Accordingly, the present invention is directed to a fin field-effect transistor and a method of fabricating the same that substantially obviates one or more problems due to limitations and disadvantages of the related art.

An advantage of the present invention is that it can provide a fin field-effect transistor and a method of fabricating the same, in which a fin structure may be provided with rounded edges to prevent a localized thinning of a gate insulating layer formed over the fin structure and to thereby prevent the occurrence of electrical shorts between the fin and a conductive layer formed on the gate insulating layer.

Another advantage of the present invention is that it can provide a fin field-effect transistor and a method of fabricating the same, which can increase product yield by reducing the occurrence of shorts between a fin and a conductive layer formed on a gate insulating layer.

Additional advantages, and features of the invention will be set forth in part in the description which follows, and in part will become apparent from the description, or may be learned by practice of the invention. The objectives and other advantages of the invention may be realized and attained by the structure particularly pointed out in the written description and claims hereof as well as the appended drawings.

To achieve these and other advantages in accordance with the purpose of the invention, as embodied and broadly described herein, a fin field-effect transistor comprises a semiconductor substrate, an insulating layer formed on an entire surface of the semiconductor substrate where a device isolation layer is formed, a fin formed on the insulating layer, the fin having rounded edges, a gate insulating layer formed on a surface of the fin, and a gate electrode formed on the gate insulating layer to be disposed on three sides of the fin.

According to another aspect of the present invention, method of fabricating a fin field-effect transistor, comprises forming an insulating layer on an entire surface of a semiconductor substrate where a device isolation layer is formed, depositing a conductive layer on the insulating layer and performing photolithography and etching processes to form a fin having rounded edges, forming a gate insulating layer on a surface of the fin, and forming a gate electrode on the gate insulating layer to be disposed on three sides of the fin.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a perspective view of a contemporary fin field-effect transistor;

FIG. 2 is a cross-sectional view along line II-II of FIG. 1;

FIG. 3 is a perspective view of a fin field-effect transistor according to an embodiment of the present invention;

FIG. 4 is a cross-sectional view along line IV-IV of FIG. 3;

FIG. 5 is a cross-sectional view along line V-V of FIG. 3; and

FIGS. 6A-6E are cross-sectional views of the fin field-effect transistor of FIG. 3, respectively illustrating steps of a method of according to an embodiment of the present invention.

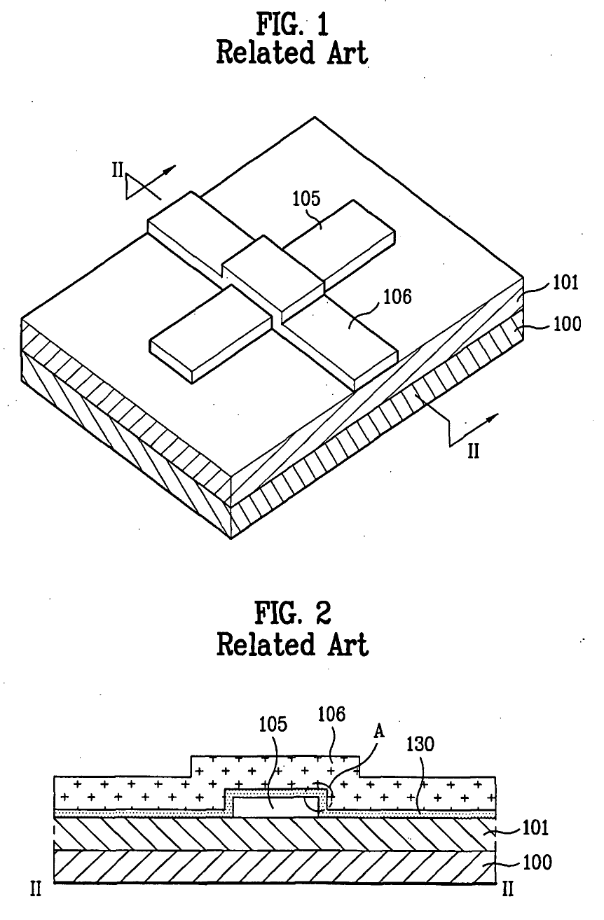

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

The fin field-effect transistor structure of an exemplary embodiment of the present invention may comprise a fin structure over an isolation layer deposited on a substrate. The edge portion of the fin structure may be rounded. A gate oxide layer is formed over the fin structure. A gate electrode is then deposited over the gate oxide layer. In this manner the gate oxide layer and the gate electrode layer enclose the fin structure by contacting the fin structure at its rounded edges.

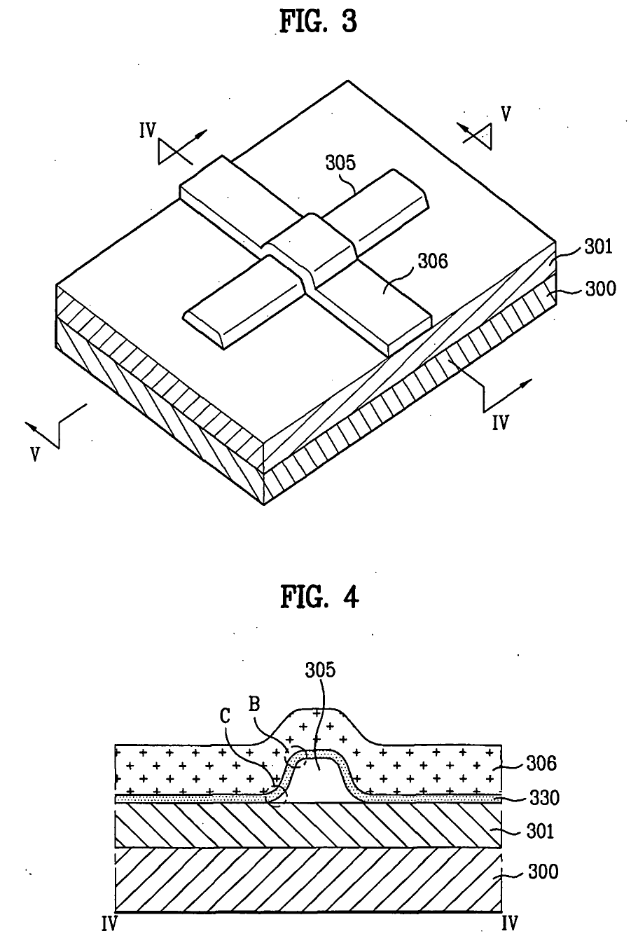

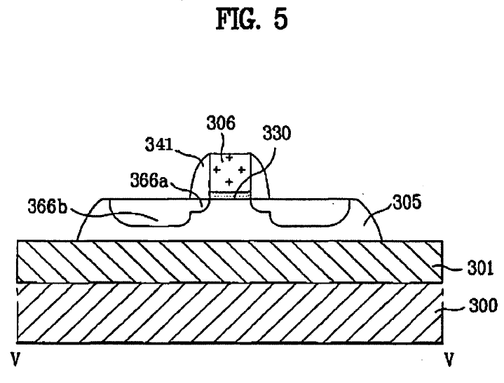

Referring to FIGS. 3, 4 and 5 the fin field-effect transistor according to an exemplary embodiment of the present invention includes a semiconductor substrate 300 where a device isolation layer (not shown) is formed, an insulating layer 301 formed on the entire surface of the semiconductor substrate, a fin 305 formed on the insulating layer and having rounded edges B and C, a gate insulating layer 330 formed on a surface of the fin, a gate electrode 306 formed on the gate insulating layer to be disposed on three sides (top side and two lateral sides) of the lengthwise structure of the fin by crossing the fin structure at substantially right angles. Sidewall spacers 341 may be formed on either side of gate electrode 306. Source/drain regions 366 and 366b are formed, proximate to each other, in a surface region of the fin 305 on either side of the gate electrode 306 that crosses over the fin and connects the source and drain regions.

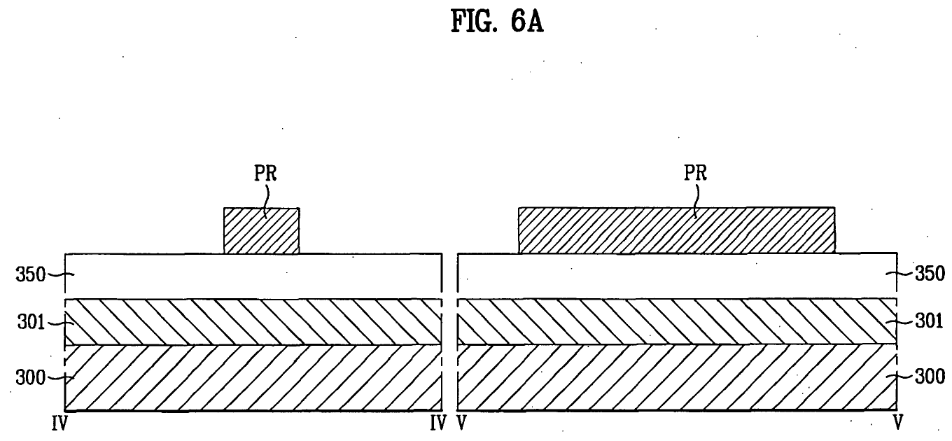

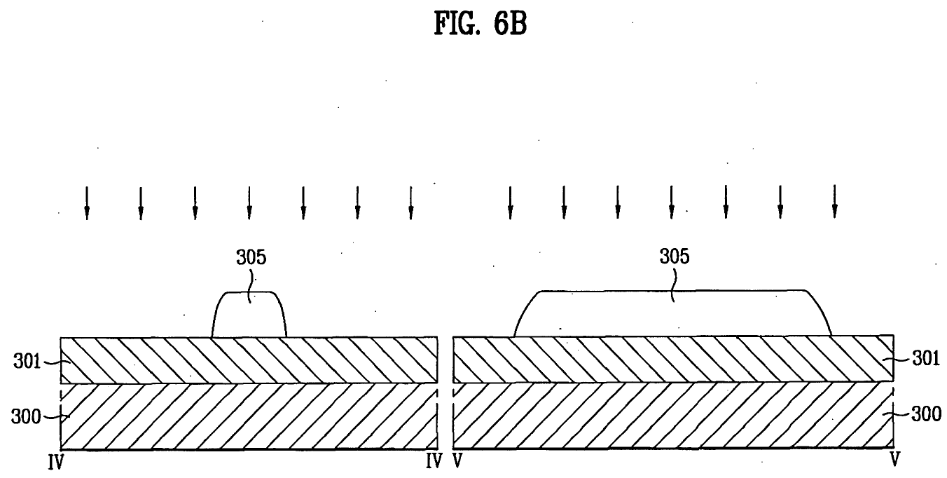

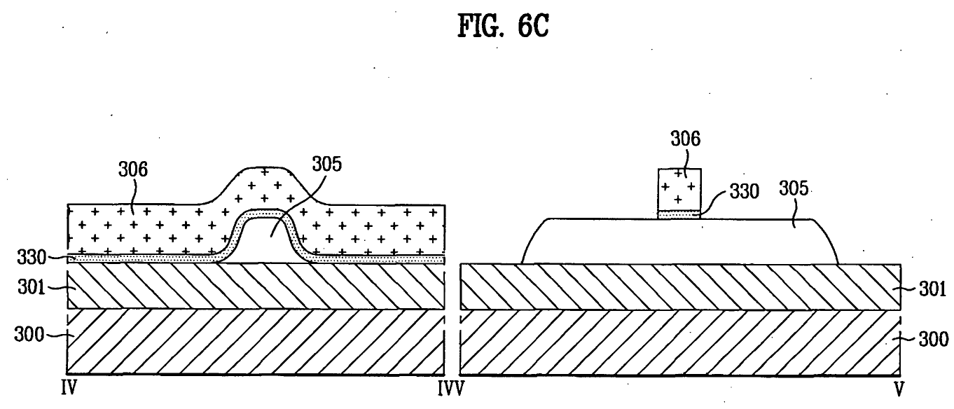

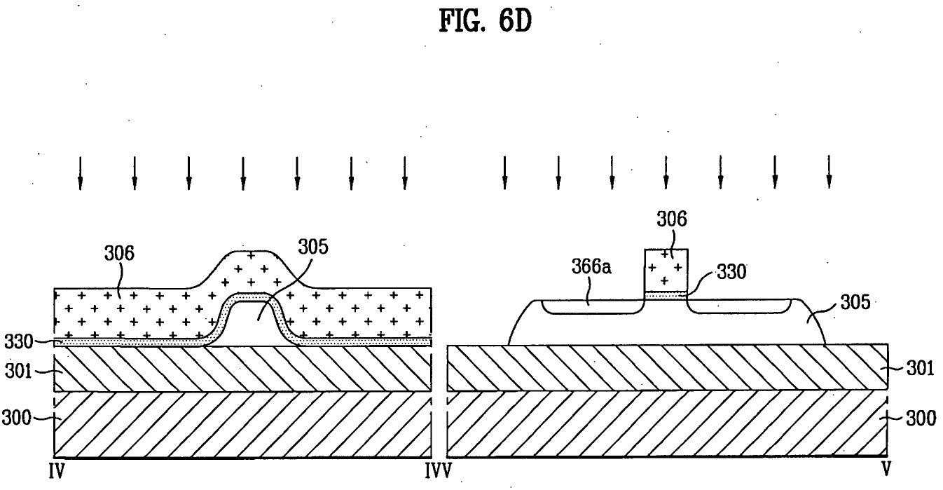

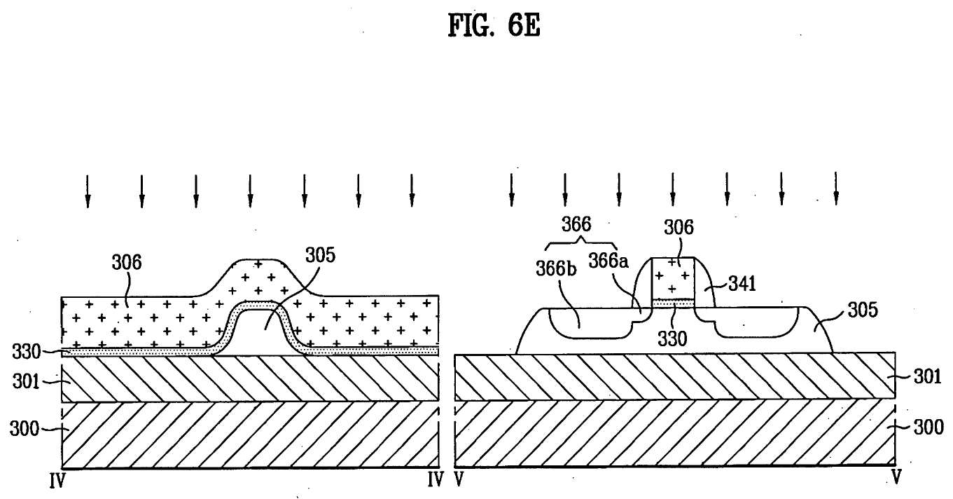

FIGS. 6A-6E illustrate an exemplary method of fabricating the fin field-effect transistor according to an embodiment of the present invention.

Referring to FIG. 6A, after providing the semiconductor substrate 300 with the device isolation layer (not shown), the insulating layer 301 and conductive layer 350 are sequentially deposited on the entire surface of the semiconductor substrate. A photoresist pattern PR is formed on the conductive layer 350.

Referring to FIG. 6B, using the photoresist pattern PR as a mask, the conductive layer 350 is etched to form the fin 305 having the rounded edges B and C, which may be formed by one of two etching processes. In a first etching method, an oxide layer (not shown) is thinly formed on the conductive layer 350 to a thickness of about 10 Å to about 400 Å, and the conductive layer on which the oxide layer is formed is etched by either dry etching or wet etching. In the second etching method, the conductive layer 350 used to make the fin is polysilicon and it is etched by isotropic dry etching. In either case, it is the rounded fin structure that may prevent the thinning phenomenon of the gate insulating layer to be formed on the fin 305.

Referring to FIG. 6C, after implanting ions into the fin 305 to form a well region (not shown), a thermal oxidation process or a rapid thermal process is performed on the entire surface of semiconductor substrate 300 on which the fin 305 is located, to form an oxide layer, and subsequently, a polysilicon layer. The polysilicon layer and the oxide layer are simultaneously patterned by photolithography to form the gate insulating layer 330 and the gate electrode 306. The oxide of the gate insulating layer 330 may be HfO₂ or HfOₓN_{y}.

Referring to FIG. 6D, a low-concentration ion implantation process for forming a shallow junction region is performed on the fin 305 to form a lightly doped junction region 366a (P− or N−).

Referring to FIG. 6E, predetermined deposition and etching processes are sequentially performed to form a spacer 341 on the sidewall of the gate electrode 306.

Thereafter, a high-concentration implantation process, using the spacer 341 as a mask, is performed to form a heavily doped junction region 366b (P+ or N+) in the fin 305, and the gate electrode 306 is doped using a low-concentration ion implantation process. Thus, a source/drain region 366, including the lightly doped junction region 366a and the heavily doped junction region 366b, is formed in the fin 305.

It will be apparent to those skilled in the art that various modifications and variations can be made in the present invention without departing from the spirit or scope of the invention. Thus, it is intended that the present invention covers such modifications provided they come within the scope of the appended claims and their equivalents.

What is claimed is:

1. A fin field-effect transistor, comprising:
a semiconductor substrate;
an insulating layer formed on an entire surface of the semiconductor substrate where a device isolation layer is formed;
a fin formed on the insulating layer, the fin having rounded edges;
a gate insulating layer formed on a surface of the fin; and
a gate electrode formed on the gate insulating layer to be disposed on three sides of the fin.

2. The fin field-effect transistor according to claim 1, wherein portions the fin is rounded at portions contacting the gate insulating layer.

3. The fin field-effect transistor according to claim 1, wherein the fin is rounded at portions contacting the insulating layer.

4. The fin field-effect transistor according to claim 1, wherein the gate electrode is made of polysilicon.

5. The fin field-effect transistor according to claim 1, wherein the gate insulating layer is made of one of HfO₂ or HfO₃N_{y}.

6. The fin field-effect transistor according to claim 1, wherein the fin comprises polysilicon.

7. The fin field-effect transistor according to claim 1, wherein the gate insulating layer and the gate electrode cross the fin at a substantially right angle.

8. The fin field-effect transistor according to claim 1, further comprising sidewall spacers on the sides of the gate electrode.

9. A method of fabricating a fin field-effect transistor, comprising:
forming an insulating layer on an entire surface of a semiconductor substrate where a device isolation layer is formed;
depositing a conductive layer on the insulating layer and performing photolithography and etching processes to form a fin having rounded edges;
forming a gate insulating layer on a surface of the fin; and
forming a gate electrode on the gate insulating layer to be disposed on three sides of the fin.

10. The method according to claim 9, further comprising:
forming an oxide layer on the conductive layer.

11. The method according to claim 10, wherein the oxide layer has a thickness of 10-400 Å.

12. The method according to claim 9, wherein the conductive layer is etched by isotropic dry etching.

13. The method according to claim 9, wherein the conductive layer is made of polysilicon.

14. The method according to claim 9, wherein the gate insulating layer is made of one of HfO₂ or HfOₓN_{y}.

15. The method according to claim 9, further comprising forming junction regions in the fin.

16. The method according to claim 9, further comprising forming sidewall spacers on the sidewalls of the gate electrode.

17. The method according to claim 16, further comprising forming junction regions in the fin, wherein the junction regions comprise a lightly doped junction region and a heavily doped junction region.

18. The method according to claim 17, wherein the sidewall spacers are used as a mask during the formation of the heavily doped junction regions.
